(19) United States
(12) Patent Application Publication
(10) Pub. No.: US 2026/0058088 A1
(43) Pub. Date: Feb. 26, 2026

(54) CHARGED PARTICLE BEAM DEVICE AND CONTROL METHOD THEREOF

(71) Applicant: Hitachi High-Tech Corporation, Tokyo (JP)

(72) Inventors: Daisuke BIZEN, Tokyo (JP); Yuzuru Mizuhara, Tokyo (JP); Shu Kizawa, Tokyo (JP)

(21) Appl. No.: 19/289,344

(22) Filed: Aug. 4, 2025

(30) Foreign Application Priority Data
Aug. 21, 2024 (JP) 2024-139517

(51) Int. Cl. H01J 37/147; H01J 37/244

(52) U.S. Cl. CPC H01J 37/1472; H01J 37/244; H01J 2237/1501; H01J 2237/2448

(57) ABSTRACT

A charged particle beam device includes: a charged particle source configured to emit a charged particle beam to be emitted onto a sample; a deflector configured to deflect trajectories of a secondary electron and a reflected electron emitted from the sample; a reflected electron detector configured to detect the reflected electron; a control unit configured to acquire an observation image based on a detection signal output from the reflected electron detector and configured to control an operation of each unit; and an absorbing plate disposed between the deflector and the reflected electron detector and including a concave portion.

### CLAIM OF PRIORITY

The present application claims priority from Japanese Patent Application JP 2024-139517 filed on Aug. 21, 2024, the content of which is hereby incorporated by reference into this application.

### BACKGROUND OF THE INVENTION

### 1. Field of the Invention

The present invention relates to a charged particle beam device that detects reflected electrons generated by irradiating a sample with a charged particle beam, and more particularly, to an improvement in signal-to-noise ratio (SNR) of the reflected electrons.

### 2. Description of Related Art

A charged particle beam device is a device that detects secondary electrons and reflected electrons generated in a sample irradiated with a charged particle beam such as an electron beam and that acquires an observation image of the sample based on a detection signal. In the case of observing a bottom of a deep hole or a deep groove of the sample, it is important to detect reflected electrons emitted from the bottom.

PTL 1 discloses that trajectories of secondary electrons and reflected electrons emitted from a sample irradiated with an electron beam are deflected, and only the reflected electrons passing through a pinhole of a diaphragm plate are detected.

### CITATION LIST

### Patent Literature

PTL 1: JP2012-15130A

### SUMMARY OF THE INVENTION

However, in PTL 1, consideration for electrons generated by collision of the secondary electrons with the diaphragm plate is insufficient. When the electrons generated in the diaphragm plate by the collision of the secondary electrons pass through the pinhole and are detected, noise is generated, and thus an SNR of the reflected electrons decreases.

Therefore, an object of the invention is to provide a charged particle beam device and a control method thereof capable of improving an SNR of reflected electrons.

In order to achieve the above object, the invention provides a charged particle beam device including: a charged particle source configured to emit a charged particle beam to be emitted onto a sample; a deflector configured to deflect trajectories of a secondary electron and a reflected electron emitted from the sample; a reflected electron detector configured to detect the reflected electron; a control unit configured to acquire an observation image based on a detection signal output from the reflected electron detector and configured to control an operation of each unit; and an absorbing plate disposed between the deflector and the reflected electron detector and including a concave portion.

The invention further includes a control method for a charged particle beam device including a charged particle source configured to emit a charged particle beam to be emitted onto a sample, a deflector configured to deflect trajectories of a secondary electron and a reflected electron emitted from the sample, a reflected electron detector configured to detect the reflected electron, a second reflected electron detector provided at an azimuth different from an azimuth of the reflected electron detector and configured to detect the reflected electron, a filter disposed between the deflector and the second reflected electron detector and configured to block the secondary electron, and a control unit configured to acquire an observation image based on a detection signal output from the reflected electron detector or the second reflected electron detector and configured to control an operation of each unit, the control method including: controlling, by the control unit, the deflector according to an energy difference between the reflected electron and the secondary electron.

According to the invention, it is possible to provide a charged particle beam device and a control method thereof capable of improving an SNR of reflected electrons.

### BRIEF DESCRIPTION OF THE DRAWINGS

FIG. 1 is a diagram showing an example of an overall configuration of a scanning electron microscope in Embodiment 1.

FIG. 2 is a diagram showing an example of an absorbing plate including a concave portion.

FIGS. 3A to 3C show other examples of the absorbing plate including a concave portion.

FIGS. 4A and 4B show other examples of a reflected electron detector.

FIG. 5 is a diagram showing an example of an overall configuration of a scanning electron microscope in Embodiment 2.

FIG. 6 is a diagram showing another example of the overall configuration of the scanning electron microscope in Embodiment 2.

FIG. 7 is a diagram showing an example of a flow of a process in Embodiment 2.

### DESCRIPTION OF EMBODIMENTS

Hereinafter, embodiments of a charged particle beam device according to the invention will be described with reference to the accompanying drawings. The charged particle beam device is a device that detects secondary electrons and reflected electrons generated from a sample by irradiating the sample with a charged particle beam such as an electron beam and that generates an observation image based on a detection signal, and is, for example, a scanning electron microscope.

### Embodiment 1

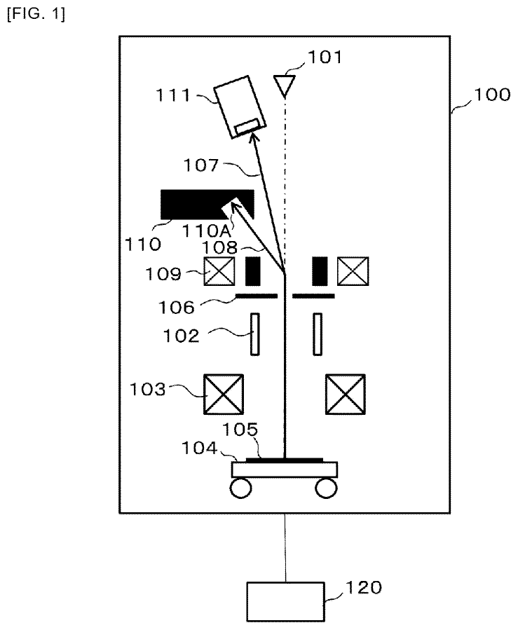

An example of an overall configuration of a scanning electron microscope in Embodiment 1 will be described with reference to FIG. 1. The scanning electron microscope includes a microscope body 100 and a control unit 120. The microscope body 100 is provided with an electron source 101, a diaphragm 106, a scanning deflector 102, an objective lens 103, a sample stage 104, a secondary particle deflector 109, an absorbing plate 110, and a reflected electron detector 111. Further, an inside of the microscope body 100 is vacuum-evacuated by a vacuum pump or the like, and a sample 105 is held on the sample stage 104.

The electron source 101 emits an electron beam to be emitted onto the sample 105. The diaphragm 106 has a hole through which the electron beam near an optical axis passes. A size of the hole is within a range of 0.1 mm to 10 mm and is switched according to an observation purpose. Note that, at least a surface of the diaphragm 106 is formed of a conductor in order to prevent charging due to collision of the electron beam.

The scanning deflector 102 deflects the electron beam so as to enable an observation region of the sample 105 to be scanned. The objective lens 103 converges the electron beam deflected by the scanning deflector 102 to the sample 105. The sample stage 104 holding the sample 105 moves in a horizontal direction or in a vertical direction to set the observation region at a predetermined position. Reflected electrons 107 and secondary electrons 108 are emitted from the sample 105 irradiated with the electron beam. Note that, when a negative voltage is applied to the sample 105 via the sample stage 104, the reflected electrons 107 and the secondary electrons 108 are accelerated by the voltage applied to the sample 105.

The secondary particle deflector 109 is a Wien filter that forms an electric field and a magnetic field orthogonal to each other, and deflects trajectories of the reflected electrons 107 and the secondary electrons 108 that pass through the diaphragm 106 without deflecting the electron beam to be emitted onto the sample 105. Note that, since an energy of the secondary electrons 108 is lower than that of the reflected electrons 107, a deflection angle of the secondary electrons 108 by the secondary particle deflector 109 is larger than that of the reflected electrons 107.

The reflected electron detector 111 detects the reflected electrons 107 deflected by the secondary particle deflector 109, and transmits a detection signal to the control unit 120. The control unit 120 is, for example, a computer, generates an observation image based on the detection signal transmitted from the reflected electron detector 111, and controls operations of the units provided in the microscope body 100.

The absorbing plate 110 is a plate that is disposed between the secondary particle deflector 109 and the reflected electron detector 111 and that absorbs the secondary electrons 108 deflected by the secondary particle deflector 109, and includes a concave portion 110A.

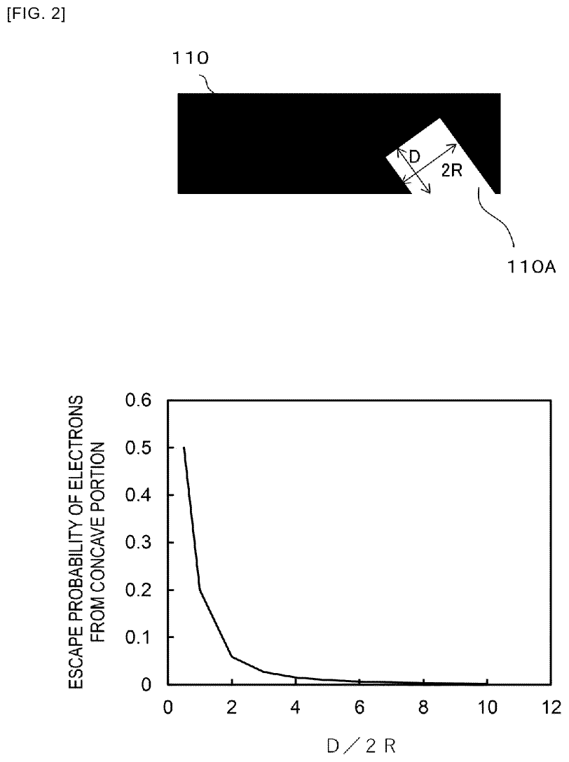

An example of the absorbing plate 110 including the concave portion 110A will be described with reference to FIG. 2. The concave portion 110A is a hole having an opening size 2R and a depth D, and is provided at a position where the secondary electrons 108 deflected by the secondary particle deflector 109 reach. Since the absorbing plate 110 includes the concave portion 110A, the secondary electrons 108 collide with the absorbing plate 110 in the concave portion 110A, and electrons generated in the absorbing plate 110 by the collision are absorbed by the absorbing plate 110 while undergoing multiple scattering in the concave portion 110A. As a result, since the electrons generated in the absorbing plate 110 can be prevented from being detected by the reflected electron detector 111, a signal-to-noise ratio (SNR) of the reflected electrons 107 can be improved.

The opening size 2R of the concave portion 110A is preferably larger than a beam diameter of the secondary electrons 108. By making the opening size 2R larger than the beam diameter of the secondary electrons 108, all of the secondary electrons 108 are incident on the concave portion 110A, and thus a ratio at which the electrons generated in the absorbing plate 110 are absorbed by the absorbing plate 110 increases. Note that, since the beam diameter of the secondary electrons 108 is approximately the same as a size of the hole of the diaphragm 106, the opening size 2R of the concave portion 110A may be larger than the size of the hole of the diaphragm 106. For example, when the size of the hole of the diaphragm 106 is within a range of 0.1 mm to 10 mm, the opening size 2R of the concave portion 110A may be 10 mm or more.

A difference between an inclination angle of the concave portion 110A with respect to the optical axis and the deflection angle of the secondary electrons 108 is preferably within a predetermined value, and it is best that the inclination angle and the deflection angle are equal. By making the difference between the inclination angle of the concave portion 110A and the deflection angle of the secondary electrons 108 within the predetermined value, an amount of the secondary electrons 108 reaching a bottom surface of the concave portion 110A increases, and thus the electrons generated in the absorbing plate 110 are likely to undergo the multiple scattering, and the ratio at which the electrons are absorbed by the absorbing plate 110 increases.

A value D/2R obtained by dividing the depth D of the concave portion 110A by the opening size 2R is preferably larger. A graph shown in FIG. 2 is a result obtained by calculating a relationship between D/2R and a probability that electrons generated according to a cos distribution by the collision of the secondary electrons 108 with the bottom surface of the concave portion 110A escape from the concave portion 110A. Note that, when tanθ=R/D, an escape probability Pe of electrons from the concave portion 110A is obtained according to the following equation.

Pe=(1−cos 2θ)/2 (Equation 1)

According to the graph in FIG. 2, when D/2R is 2 or more, Pe can be less than 10%.

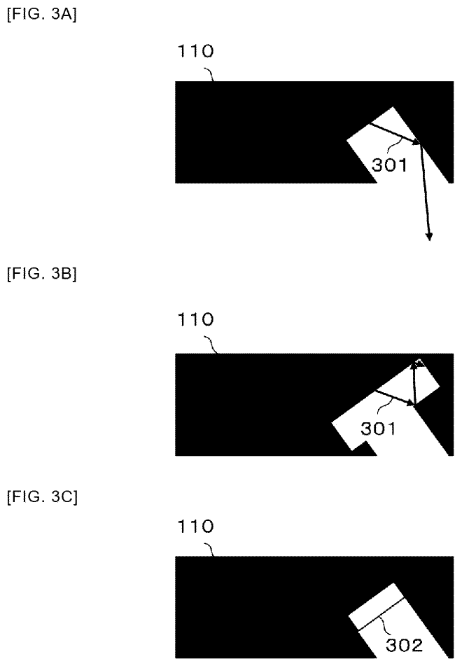

Other examples of the absorbing plate 110 including the concave portion 110A will be described with reference to FIGS. 3A to 3B. FIG. 3A shows a case where electrons 301 generated on the bottom surface of the concave portion 110A emit secondary electrons or reflected electrons on a side surface of the concave portion 110A. It is preferable that such secondary electrons and reflected electrons are not detected by the reflected electron detector 111. Therefore, as shown in FIG. 3B, by making a size of the bottom surface of the concave portion 110A larger than the opening size, a probability that the electrons 301 generated on the bottom surface emit the secondary electrons or the reflected electrons on the side surface of the concave portion 110A may be reduced.

As shown in FIG. 3C, a secondary electron detector 302 that detects the secondary electrons 108 may be provided on the bottom surface of the concave portion 110A. The secondary electron detector 302 detects the secondary electrons 108 incident on the concave portion 110A, and transmits a detection signal to the control unit 120. The control unit 120 may generate an observation image based on the detection signal transmitted from the secondary electron detector 302, or may perform focus adjustment of the objective lens 103 or position adjustment of the sample stage 104.

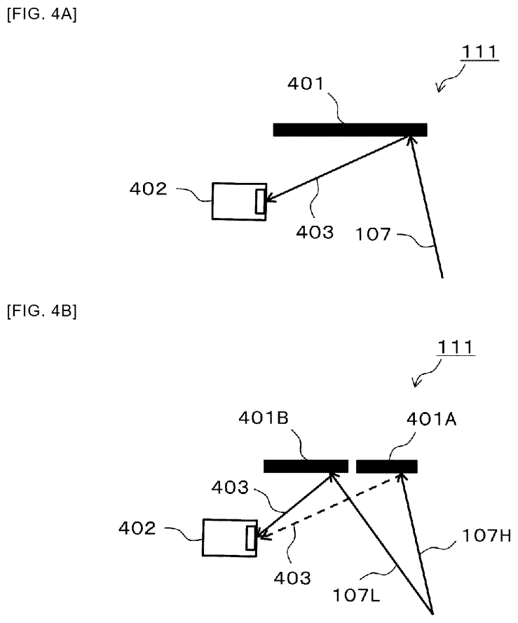

Other examples of the reflected electron detector 111 will be described with reference to FIGS. 4A and 4B. The reflected electron detector 111 shown in FIG. 4A includes a reflection plate 401 and a detector 402. The reflection plate 401 is provided at a position where the reflected electrons 107 deflected by the secondary particle deflector 109 reach, and emits reflection plate electrons 403 when the reflected electrons 107 collide therewith. The reflection plate electrons 403 are secondary electrons emitted from the reflection plate 401 by the collision with the reflected electrons 107. The detector 402 detects the reflection plate electrons 403 emitted from the reflection plate 401 and transmits a detection signal to the control unit 120. Note that, since an energy of the reflection plate electrons 403 is as low as 50 eV or less, the detector 402 that forms an electric field of attracting the reflection plate electrons 403 is used.

In the reflected electron detector 111 shown in FIG. 4B, the reflection plate 401 in FIG. 4A is divided into an inner reflection plate 401A and an outer reflection plate 401B, and voltages are individually applied to the inner reflection plate 401A and the outer reflection plate 401B under the control of the control unit 120. Note that, the inner reflection plate 401A is disposed on a side close to the electron source 101, and the outer reflection plate 401B is disposed on a side far from the electron source 101.

The reflected electrons 107 include high-energy reflected electrons 107H having a relatively high energy and low-energy reflected electrons 107L having a relatively low energy. Since a deflection angle of the high-energy reflected electrons 107H is relatively small, the high-energy reflected electrons 107H collide with the inner reflection plate 401A to cause the reflection plate electrons 403 to be emitted from the inner reflection plate 401A. Since a deflection angle of the low-energy reflected electrons 107L is relatively large, the low-energy reflected electrons 107L collide with the outer reflection plate 401B to cause the reflection plate electrons 403 to be emitted from the outer reflection plate 401B.

When the control unit 120 applies a positive voltage, for example, 50 V, to the inner reflection plate 401A, the reflection plate electrons 403 emitted from the inner reflection plate 401A are returned to the inner reflection plate 401A. As a result, only the reflection plate electrons 403 emitted from the outer reflection plate 401B are detected by the detector 402, so that an observation image by the low-energy reflected electrons 107L is generated. When the control unit 120 applies a positive voltage to the outer reflection plate 401B, an observation image by the high-energy reflected electrons 107H is generated. That is, by individually applying the voltages to the inner reflection plate 401A and the outer reflection plate 401B divided as shown in FIG. 4B, energy discrimination of the reflected electrons 107 can be performed.

### Embodiment 2

In Embodiment 1, separation of the reflected electrons 107 and the secondary electrons 108 using the difference in deflection angle by the secondary particle deflector 109 based on an energy difference between the reflected electrons 107 and the secondary electrons 108 is described. Depending on a value of the negative voltage applied to the sample 105 via the sample stage 104, the energy difference between the reflected electrons 107 and the secondary electrons 108 is small, and it may be difficult to separate the reflected electrons 107 and the secondary electrons 108 in the secondary particle deflector 109. In Embodiment 2, separation of the reflected electrons 107 and the secondary electrons 108 regardless of the energy difference will be described.

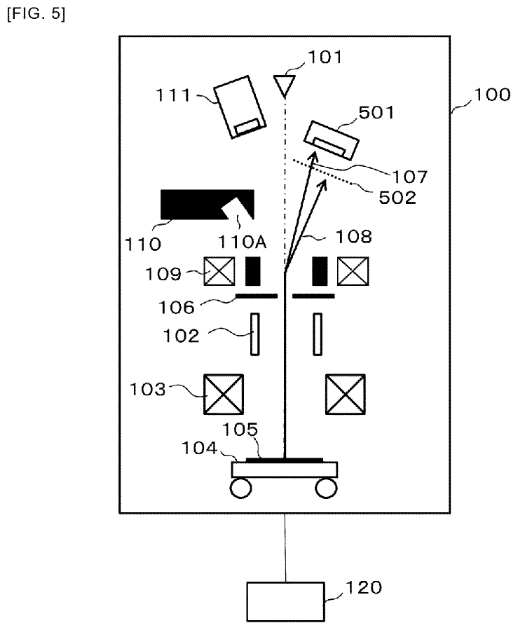

An example of an overall configuration of a scanning electron microscope in Embodiment 2 will be described with reference to FIG. 5. Note that, the scanning electron microscope shown in FIG. 5 is obtained by adding a second reflected electron detector 501 and a filter 502 to that in FIG. 1.

Similar to the reflected electron detector 111, the second reflected electron detector 501 detects the reflected electrons 107 deflected by the secondary particle deflector 109, and transmits a detection signal to the control unit 120. Note that, the second reflected electron detector 501 is disposed at an azimuth different from that of the reflected electron detector 111, and for example, when the reflected electron detector 111 is disposed in a direction at an azimuth angle of 0°, the second reflected electron detector 501 is disposed in a direction at an azimuth angle of 180°.

The filter 502 is a mesh-shaped electrode disposed between the secondary particle deflector 109 and the second reflected electron detector 501, and blocks the secondary electrons 108 by applying a negative voltage. By the filter 502 blocking the secondary electrons 108, the second reflected electron detector 501 detects only the reflected electrons 107 among the reflected electrons 107 and the secondary electrons 108 deflected by the secondary particle deflector 109.

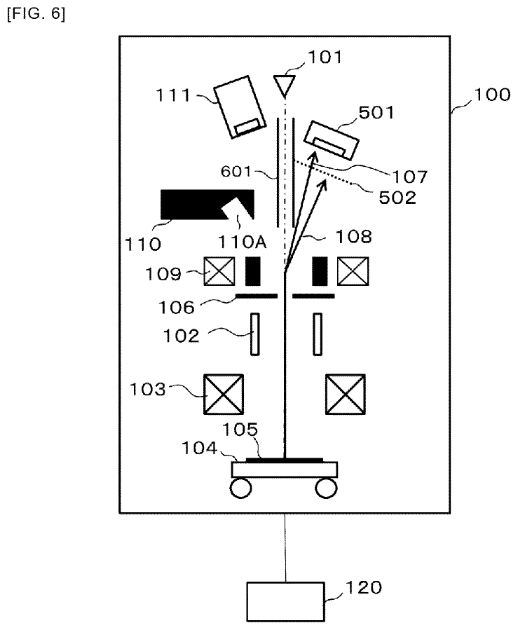

Another example of the overall configuration of the scanning electron microscope in Embodiment 2 will be described with reference to FIG. 6. Note that, in a scanning electron microscope shown in FIG. 6, a pipe 601 is added to that in FIG. 5. The pipe 601 is a metal thin tube having a ground potential, and is disposed to cover the electron beam emitted from the electron source 101 near the second reflected electron detector 501 and the filter 502. The electron beam covered by the pipe 601 is not deflected by an electric field formed by the filter 502 or the like.

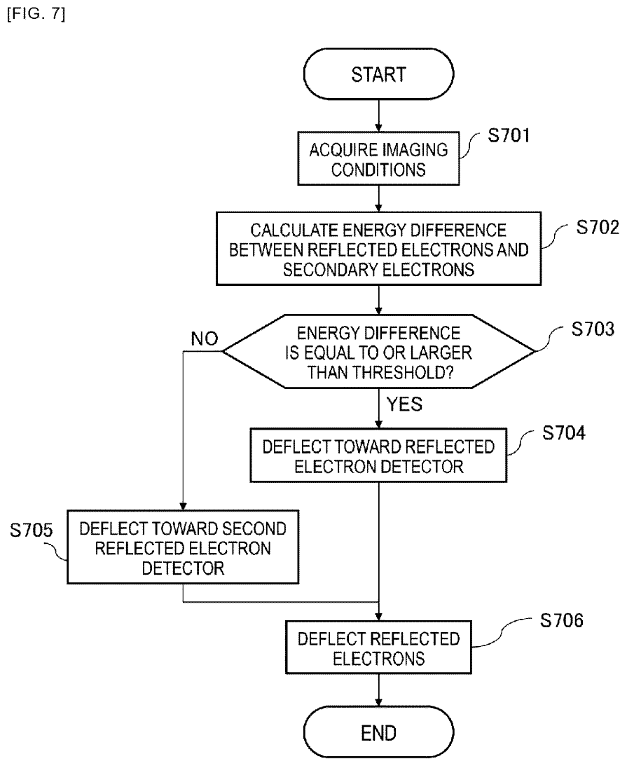

An example of a flow of a process in Embodiment 2 will be described for each process step with reference to FIG. 7.

### S701

The control unit 120 acquires imaging conditions. Note that, the imaging conditions include the voltages to be applied to the electron source 101 and the sample 105.

### S702

The control unit 120 calculates an energy difference between the reflected electrons 107 and the secondary electrons 108 emitted from the sample 105 and reaching the secondary particle deflector 109 based on the imaging conditions acquired in S701. For example, when the voltage applied to the electron source 101 is −11 kV and the voltage applied to the sample 105 is −1 kV, the energy of the reflected electrons 107 emitted from the sample 105 is 10 keV and the energy of the secondary electrons 108 emitted from the sample 105 is 50 eV. Since the reflected electrons 107 and the secondary electrons 108 are accelerated by the voltage applied to the sample 105 before reaching the secondary particle deflector 109, the energy of the reflected electrons 107 becomes 11 keV and the energy of the secondary electrons 108 becomes about 1 keV. As a result, the energy difference therebetween is about 10 keV. When −5 kV is applied to the electron source 101 and −4 kV is applied to the sample 105, the reflected electrons 107 and the secondary electrons 108 reaching the secondary particle deflector 109 have an energy of 5 keV and about 4 keV, respectively, and the energy difference therebetween is about 1 keV.

### S703

The control unit 120 determines whether the energy difference calculated in S702 is equal to or larger than a threshold. If the energy difference is equal to or larger than the threshold, the process proceeds to S704, and if the energy difference is not equal to or larger than the threshold, the process proceeds to S705. The threshold is set in advance. For example, when the threshold is 2 keV, −11 kV is applied to the electron source 101, and −1 kV is applied to the sample 105, the energy difference between the reflected electrons 107 and the secondary electrons 108 is about 10 keV, which is equal to or larger than the threshold, and thus the process proceeds to S704. When the threshold is 2 keV, −5 kV is applied to the electron source 101, and −4 kV is applied to the sample 105, the energy difference between the reflected electrons 107 and the secondary electrons 108 is about 1 keV, which is less than the threshold, and thus the process proceeds to S705.

### S704

The control unit 120 controls the secondary particle deflector 109 to deflect the trajectories of the reflected electrons 107 and the secondary electrons 108 emitted from the sample 105 toward the reflected electron detector 111. The deflected secondary electrons 108 are absorbed by the absorbing plate 110 including the concave portion 110A, and the reflected electrons 107 are incident on the reflected electron detector 111.

### S705

The control unit 120 controls the secondary particle deflector 109 to deflect the trajectories of the reflected electrons 107 and the secondary electrons 108 emitted from the sample 105 toward the second reflected electron detector 501. The deflected secondary electrons 108 are blocked by the filter 502, and the reflected electrons 107 are incident on the reflected electron detector 111.

### S706

The reflected electron detector 111 or the second reflected electron detector 501 detects the reflected electrons 107, and transmits the detection signal to the control unit 120. The control unit 120 to which the detection signal is transmitted generates the observation image based on the detection signal. The generated observation image is displayed on a display device such as a liquid crystal display or stored in a storage device such as a hard disk drive (HDD) or a solid state drive (SSD).

According to the flow of the process described with reference to FIG. 7, the reflected electrons 107 and the secondary electrons 108 can be separated from each other regardless of the energy difference.

The embodiments of the electron microscope of the invention are described above. The invention is not limited to the above embodiments, and can be embodied by modifying components in a range not departing from the gist of the invention. A plurality of components disclosed in the above embodiments may be combined appropriately. A part of components may be deleted from all components disclosed in the above embodiments.

What is claimed is:

1. A charged particle beam device comprising:
a charged particle source configured to emit a charged particle beam to be emitted onto a sample;
a deflector configured to deflect trajectories of a secondary electron and a reflected electron emitted from the sample;
a reflected electron detector configured to detect the reflected electron;
a control unit configured to acquire an observation image based on a detection signal output from the reflected electron detector and configured to control an operation of each unit; and
an absorbing plate disposed between the deflector and the reflected electron detector and including a concave portion.

2. The charged particle beam device according to claim 1, wherein
an opening size of the concave portion is larger than a beam diameter of the secondary electron.

3. The charged particle beam device according to claim 1, wherein
a difference between an inclination angle of the concave portion with respect to an optical axis and a deflection angle of the secondary electron is within a predetermined value.

4. The charged particle beam device according to claim 1, wherein
a value D/2R obtained by dividing a depth D of the concave portion by an opening size 2R is 2 or more.

5. The charged particle beam device according to claim 1, wherein
a size of a bottom surface of the concave portion is larger than an opening size of the concave portion.

6. The charged particle beam device according to claim 1, wherein
a secondary electron detector configured to detect the secondary electron is provided on a bottom surface of the concave portion.

7. The charged particle beam device according to claim 1, wherein
the reflected electron detector includes a reflection plate with which the reflected electron collides, and a reflection plate electron detector configured to detect a reflection plate electron emitted from the reflection plate.

8. The charged particle beam device according to claim 7, wherein
the reflection plate is divided into an inner reflection plate disposed on a side close to the charged particle source and an outer reflection plate disposed on a side far from the charged particle source, and
the control unit individually applies a voltage to the inner reflection plate and the outer reflection plate.

9. The charged particle beam device according to claim 1, further comprising:
a second reflected electron detector provided at an azimuth different from an azimuth of the reflected electron detector and configured to detect the reflected electron; and
a filter disposed between the deflector and the second reflected electron detector and configured to block the secondary electron.

10. The charged particle beam device according to claim 9, further comprising:
a pipe disposed near the reflected electron detector and the filter to cover the charged particle beam.

11. The charged particle beam device according to claim 9, wherein
the control unit controls the deflector according to an energy difference between the reflected electron and the secondary electron.

12. A control method for a charged particle beam device including a charged particle source configured to emit a charged particle beam to be emitted onto a sample, a deflector configured to deflect trajectories of a secondary electron and a reflected electron emitted from the sample, a reflected electron detector configured to detect the reflected electron, a second reflected electron detector provided at an azimuth different from an azimuth of the reflected electron detector and configured to detect the reflected electron, a filter disposed between the deflector and the second reflected electron detector and configured to block the secondary electron, and a control unit configured to acquire an observation image based on a detection signal output from the reflected electron detector or the second reflected electron detector and configured to control an operation of each unit, the control method comprising:
controlling, by the control unit, the deflector according to an energy difference between the reflected electron and the secondary electron.
